(19) United States
(12) Patent Application Publication
(10) Pub. No.: US 2025/0221139 A1
(43) Pub. Date: Jul. 3, 2025

(54) METALLIC REINFORCED TRANSPARENT CONDUCTIVE OXIDES

(71) Applicant: Massachusetts Institute of Technology, Cambridge, MA (US)

(72) Inventors: Moungi G. Bawendi, Cambridge, MA (US); Mattias Grotevent, Somerville, MA (US)

(73) Assignee: Massachusetts Institute of Technology, Cambridge, MA (US)

(21) Appl. No.: 18/841,643

(22) PCT Filed: Feb. 28, 2023
(86) PCT No.: PCT/US2023/063394

§ 371 Date: Aug. 26, 2024

Related U.S. Application Data
(60) Provisional application No. 63/314,910, filed on Feb. 28, 2022.

(51) Int. Cl. H10K 30/83; C09J 9/02; C09J 11/04; H10K 30/50; H10K 30/85; H10K 30/86; H10K 85/50; H10K 85/60

(52) U.S. Cl. CPC H10K 30/83; C09J 9/02; C09J 11/04; H10K 30/50; H10K 30/85; H10K 30/86; H10K 85/50; H10K 85/615; H10K 85/633

(57) ABSTRACT

A solar cell can include a first transparent conductive oxide (TCO) layer proximate to a first charge transport layer; a second TCO layer proximate to a second charge transport layer; a perovskite layer disposed between first and second charge transport layers; a first plurality of electrically conductive lines disposed between the first TCO layer and the first charge transport layer, and/or a second plurality of electrically conductive lines disposed between the second TCO layer and second charge transport layer.

### CLAIM OF PRIORITY

This application claims priority to U.S. Provisional Patent Application No. 63/314,910, filed Feb. 28, 2022, which is incorporated by reference in its entirety.

### BACKGROUND

Bifacial solar cells harness the energy of direct and indirect (back-side) illumination which increases their yield especially under cloudy conditions as compared to conventional monofacial solar cells. Therefore, bifacial solar cells can absorb about 30% more light than monofacial solar cells depending on the reflectivity of the ground (albedo effect). It is expected that bifacial solar cells will have an increased share of the worldwide solar cell installation within the next decade.

Renewable energies are increasingly important to reach the sustainability goals set by the 2016 Paris Climate Agreement. Most countries (including the US) are increasing their investments into renewable energies. The US solar cell market size was approximately $10 bn in 2021 with a 10% growth rate, and the worldwide solar cell market was over $100 bn.

Transparent conductive electrodes are required in solar cells because they are transparent to light and electrically conductive to extract the photogenerated charge carriers. The conductivity of transparent conductive oxides (TCOs) is limited, leading to an increase in serial resistance and a reduction in solar cell efficiency. While smaller solar cells do not significantly suffer under serial resistance due to their small size, it is a very important parameter for solar modules which are widely used to harness the solar energy.

### SUMMARY

This Summary introduces a selection of concepts in simplified form that are described further below in the Description. This Summary neither identifies key or essential features, nor limits the scope, of the claimed subject matter.

In one aspect, a solar cell includes a first transparent conductive oxide (TCO) layer proximate to a first charge transport layer; a second TCO layer proximate to a second charge transport layer; a perovskite layer disposed between first and second charge transport layers; and (a) a first plurality of electrically conductive lines disposed between the first TCO layer and the first charge transport layer; or (b) a second plurality of electrically conductive lines disposed between the second TCO layer and second charge transport layer; or (c) both (a) and (b).

In another aspect, a bifacial solar cell can include a hole transport layer (HTL), a perovskite layer, an electron transport layer (ETL), wherein the HTL, perovskite, and ETL layers lie between two transparent conductive oxide (TCO) layers, wherein a first metal grid lies within and strengthens the HTL layer, and wherein a second metal grid lies within and strengthens the ETL layer.

In another aspect, a method of producing photogenerated current, includes illuminating a solar cell which includes a first transparent conductive oxide (TCO) layer proximate to a first charge transport layer; a second TCO layer proximate to a second charge transport layer; a perovskite layer disposed between first and second charge transport layers; and (a) a first plurality of electrically conductive lines disposed between the first TCO layer and the first charge transport layer; or (b) a second plurality of electrically conductive lines disposed between the second TCO layer and second charge transport layer; or (c) both (a) and (b); thereby producing photogenerated current.

In some embodiments, the solar cell is a bifacial solar cell. The first plurality of electrically conductive lines and second plurality of electrically conductive lines can each independently include copper (Cu), silver (Ag), zinc (Zn), gold (Au), or aluminum (Al).

In some embodiments, the first charge transport layer can include Spiro-MeOTAD. The second charge transport layer can include SnO₂.

In some embodiments, the first plurality of electrically conductive lines can be configured as a periodic pattern of lines. The first plurality of electrically conductive lines can be configured as a grid. The first plurality of electrically conductive lines can be configured to carry photogenerated current.

In some embodiments, the second plurality of electrically conductive lines can be configured as a periodic pattern of lines. The second plurality of electrically conductive lines can be configured as a grid. The second plurality of electrically conductive lines can be configured to carry photogenerated current.

In some embodiments, the solar cell can include a first adhesive layer disposed between the first TCO layer and the first plurality of electrically conductive lines. The first adhesive layer can include titanium (Ti) or chromium (Cr). The first adhesive layer can include an electrically conductive material. The first adhesive layer can include an electrically insulating material.

In some embodiments, the solar cell can include a second adhesive layer disposed between the second TCO layer and the second plurality of electrically conductive lines. The second adhesive layer can include titanium (Ti), thiophenol, hexanethiol, or trioctylphosphine oxide. The second adhesive layer can include an electrically conductive material. The second adhesive layer can include an electrically insulating material.

In some embodiments, the first metal grid can contact the TCO layer adjacent to the HTL.

In some embodiments, the second metal grid can contact the TCO layer adjacent to the ETL.

In some embodiments, the first metal grid and second metal grid each can include gold (Au) or aluminum (Al).

In some embodiments, the first metal grid can be in contact with the TCO layer through a thin adhesive layer.

In some embodiments, the second metal grid can be in contact with the TCO layer through a thin adhesive layer.

In some embodiments, the adhesive layer can include Ti, thiophenol, hexanethiol, or trioctylphosphine oxide.

In some embodiments, the thin adhesive layer can consist of an electrically conductive material.

In some embodiments, the thin adhesive layer can consist of an electrically insulating material.

In some embodiments, the HTL layer can include 2,2′,7,7′-tetrakis [N,N-di(4-methoxyphenyl)amino]-9,9′-spirobifluorene (spiro-MeOTAD).

In some embodiments, the ETL layer can include SnO₂.

In some embodiments, the first and second metal grids can be periodically disposed in the HTL and ETL conductive layers, respectively.

In some embodiments, the first and second metal grids can be configured to carry a photogenerated current.

In another aspect, the bifacial solar cell disclosed herein can produce a photogenerated current.

The following Description references the accompanying drawings which form a part this application, and which show, by way of illustration, specific example implementations. Other implementations may be made without departing from the scope of the disclosure.

### BRIEF DESCRIPTION OF THE DRAWINGS

FIG. 1A is a schematic of small-area bifacial PSC with low lateral conductivity in the TCOs comprised of fluorine-doped tin oxide (FTO) or indium-doped tin oxide (ITO). The PSC comprises a hole transport layer (HTL), e.g., comprising 2,2′,7,7′-tetrakis[N,N-di(4-methoxyphenyl)amino]-9,9′-spirobifluorene (spiro-MeOTAD); a perovskite layer; and an electron transport layer (ETL), e.g., comprising SnO₂. FIG. 1B shows metal lines (e.g., gold (Au)) between the TCOs and the HTL and ETL, respectively. The inset shows optional adhesion materials for the metal in the ETL or the HTL, including Ti as an adhesive or TiO₂ as an adhesive for SnO₂.

FIG. 2 illustrates a small-area bifacial PSC (upper left) and shows photographs of the back and front of the same. Arrows indicate the location of the illustrated features in the photographs.

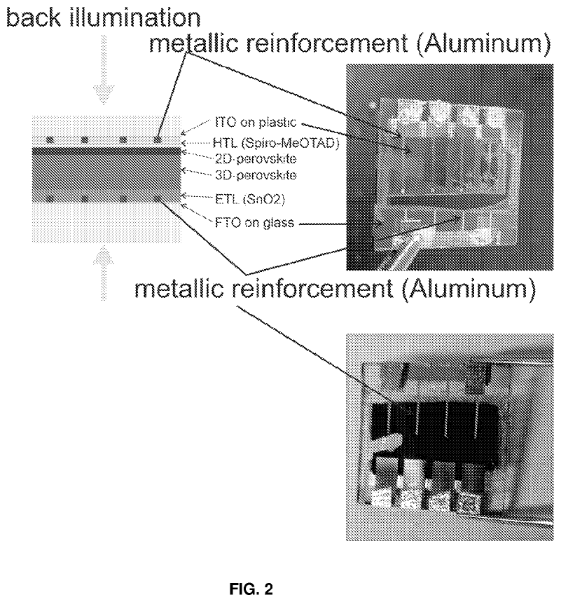

FIG. 3 is a graph showing electrical properties of a PSC of the kind illustrated in FIG. 2.

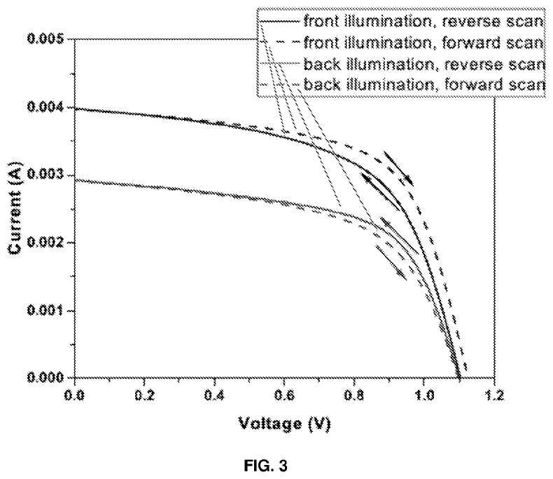

FIG. 4 is a schematic of a cell.

### DETAILED DESCRIPTION

A perovskite solar cell (PSC) is a type of solar cell which includes a perovskite-structured compound, most commonly a hybrid organic-inorganic lead or tin halide-based material, as the light-harvesting active layer.

Perovskite solar cells are an emerging solar cell technology offering high light conversion efficiencies at low fabrication and energy costs. The active perovskite layer as well as organic charge transport layers are fabricated below 150° C. Higher temperatures will lead to degradation of those layers.

A scientific problem is that bifacial solar cells require two transparent electrodes (usually transparent conductive oxides) on each side of the active semiconductor layer. Unfortunately, the resistivity of transparent conductive oxides is much larger in comparison with metals. This leads to higher resistivity and solar cell efficiency losses.

A perovskite material can have formula (Ia):

APbX₃ (Ia)

or formula (Ib):

ASnX₃ (Ib)

where A is an organic or molecular cation (such as ammonium, methylammonium, formamidinium, phosphonium, cesium, etc.), and X is a halide ion (such as I, Br, or Cl).

Alternatively, a perovskite material can have the formula (II):

AₓA′₁₋ₓB_{y}B′_{1-y}O_{3±δ} (II)

where each of A and A′, independently, is a rare earth, alkaline earth metal, or alkali metal, x is in the range of 0 to 1, each of B and B′, independently, is a transition metal, y is in the range of 0 to 1, and δ is in the range of 0 to 1. 8 can represent the average number of oxygen-site vacancies (i.e., −δ) or surpluses (i.e., +δ); in some cases, δ is in the range of 0 to 0.5, 0 to 0.25, 0 to 0.15, 0 to 0.1, or 0 to 0.05. For clarity, it is noted that in formula (I), B and B′ do not represent the element boron, but instead are symbols that each independently represent a transition metal. In some cases, δ can be approximately zero, i.e., the number of oxygen-site vacancies or surpluses is effectively zero. The material can in some cases have the formula AB_{y}B′_{1-y}O₃ (i.e., when x is 1 and δ is 0); AₓA′₁₋ₓBO₃ (i.e., when y is 1 and δ is 0); or ABO₃ (i.e., when x is 1, y is 1 and δ is 0). The perovskite can form a two dimensional layer (2D-perovskite) or a three dimensional layer (3D-perovskite).

Rare earth metals include Sc, Y, La, Ce, Pr, Nd, Pm, Sm, Eu, Gd, Tb, Dy, Ho, Er, Tm, Yb, or Lu. Alkaline earth metals include Be, Mg, Ca, Sr, Ba, and Ra. Alkali metals include Li, Na, K, Rb, and Cs. Transition metals include Sc, Ti, V, Cr, Mn, Fe, Co, Ni, Cu, Zn, Y, Zr, Nb, Mo, Tc, Ru, Rh, Pd, Ag, Cd, Hf, Ta, W, Re, Os, Ir, Pt, Au, or Hg. Particularly useful alkaline earth metals can include Ca, Sr, and Ba. Particularly useful transition metals can include first-row transition metals, for example, Cr, Mn, Fe, Co, Ni, and Cu. Representative materials of formula (I) include calcium titanate (CaTiO₃), barium titanate (BaTiO₃), strontium titanate (SrTiO₃), barium ferrite (BaFeO₃), KTaO₃, NaNbO₃, PbTiO₃, LaMnO₃, SrZrO₃, SrHfO₃, SrSnO₃, SrFeO₃, BaZrO₃, BaHfO₃, KNbO₃, BaSnO₃, EuTiO₃, RbTaO₃, GdFeO₃, PbHfO₃, LaCrO₃, PbZrO₃, or LiNbO₃.

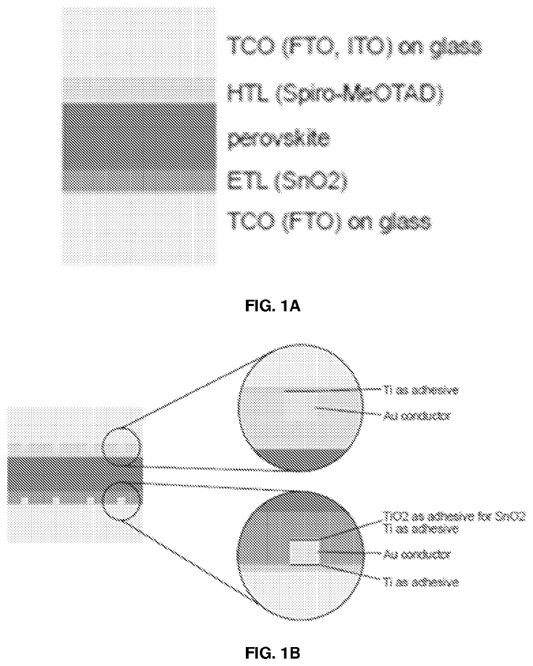

FIG. 1A shows a typical schematic representation of a cross-section of a small-area (≤1 cm²) perovskite solar cell. FIG. 1B shows a cross-section of a large-area perovskite solar cell (>1 cm²) with metal lines providing enhanced conductivity to the transparent conductive oxides. Adhesion between the selected metal and the hole transport layer (HTL) or electron transport layer (ETL) can be facilitated with a surface treatments. For example, a thin titanium or chromium layer readily forms chemical bonds to the transparent conductive oxide as well as metallic bonds to the metal lines. The metal lines can be formed of, for example, copper (Cu), silver (Ag), zinc (Zn), gold (Au), or aluminum (Al). At the interface of organic hole transporting layer and the metal lines, a molecule such as thiophenol, hexanethiol, or trioctylphosphine oxide may be used which would selectively bind to the metal electrode and increases the adhesion to the hole transporting layer. The adhesion layer can be designed to be electrically insulating or conductive if desired.

The metal lines (which may optionally be in a grid configuration) can be said to enhance or reinforce the conductivity of the transparent conductive oxide layer. The metal lines can conduct high current. Therefore, the metal lines and grids can be wide or thick. The more lines you have, the more shading can result which can reduce efficiency. As a result, so the spacing would be larger. The metal lines can have a thickness of 50 nm to 10 micrometers. For example, the metal lines can have a thickness of about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, about 500 nm, about 1000 nm, about 2000 nm, about 3000 nm, about 4000 nm, about 5000 nm, about 6000 nm, about 7000 nm, about 8000 nm, about 9000 nm, or about 10000 nm. The metal lines can have a width of 5 micrometers to 2 mm. The metal line can have a width of about 5 micrometers, about 10 micrometers, about 20 micrometers, about 30 micrometers, about 40 micrometers, about 50 micrometers, about 75 micrometers, about 100 micrometers, about 250 micrometers, about 500 micrometers, about 750 micrometers, about 1000 micrometers, about 1250 micrometers, about 1500 micrometers, about 1750 micrometers, or about 2000 micrometers. When the metal lines for a grid, the grid include periodic spacing between lines, perpendicular orientation of lines, or random distributions of lines. The metal lines can have a spacing of 1 mm to 3 cm. Spacing between metal lines can be about 1 mm, about 3 mm, about 5 mm, about 8 mm, about 10 mm, about 15 mm, about 18 mm, about 20 mm, about 22 mm, about 25 mm, about 28 mm, or about 30 mm.

The hole transport layer can include Spiro-OMeTAD, PEDOT: PSS, PTAA (poly[bis(4-phenyl)(2,4,6-trimethylphenyl)amine]) or P3HT.

The electron transport layer can include tin oxides, zinc-tin oxides, magnesium-tin oxides, aluminum-tin oxides, or tin-titanium oxides.

Photogenerated current needs to travel through the transparent conductive oxide horizontally to leave the solar cell. Resistance in the TCO layer increases with the distance for the charge carriers must travel, reducing efficiency. Presently, to keep the travel distance for charge carriers in the transparent conductive oxide short, a large area perovskite module may be divided into smaller subcells by so called P1-P2-P3 scribing (or alternatively shingling). P1, P2, and P3 scribes correspond to the three scribing steps of the process for building the monolithic interconnections that add voltages between subcells in modules. The P1 and P3 steps are aimed at isolating the back contact layers of neighboring subcells and the P2 step creates an electrical path between the back contact of a subcell with the front contact of an adjacent subcell. This way the current needs to only travel for a short distance until it reaches the next subcell, while the generated photovoltage is added together from all solar subcells.

Other solar technologies like silicon solar cells only use a metal grid without the transparent conductive oxide, as the charge carrier diffusion length is a few millimeters in silicon, so the charge carriers can travel within the silicon absorption layer towards the electrodes. However, this is not the case in perovskite solar cells as the charge carrier diffusion length is 10 to 1000 times lower than in silicon solar cells.

Bifacial cadmium telluride (CdTe) and copper indium gallium diselenide (CIGS) solar cells in which the conductivity of the bottom TCO is enhanced by a metal line may be difficult to fabricate. These solar cells are typically made starting from a TCO followed by high temperature deposition of the CdTe layer or the CIGS layer. Metallic lines would not withstand such high temperatures, but would likely melt and diffuse into the active semiconductor area, leading to significant performance losses. This is why P1-P2-P3 scribing or shingling is used to avoid high resistivity in the TCO layer.

Solar cells having electrically conductive lines as described herein can provide a distinct advantage over solar cells built by scribing. The electrically conductive lines can be metal lines. Photogenerated current in the TCO only needs to travel to the next metal line, where the high conductivity of the metal can easily extract the photogenerated charge carriers without parasitic resistance. For solar modules built by scribing, the charge carriers only travel in one direction. In comparison, the metal lines accept charge carriers from any direction in the TCO layer, which allows a larger periodicity of the metal lines (i.e., greater spacing between lines) as compared to the scribing periodicity. This will also reduce the shading of the perovskite solar cell and can lead to a higher solar cell efficiency for solar cell modules.

Fabrication of the solar cells described herein can be performed using one metallization step to form conductive lines. In contrast, scribing can involve three laser etching processes and one metallization step.

Both monofacial and bifacial solar cells can benefit from the conductive lines as described herein. The lines may be placed above or below the transparent conductive oxide, so long as the lines are in electrical communication with the transparent conductive oxide.

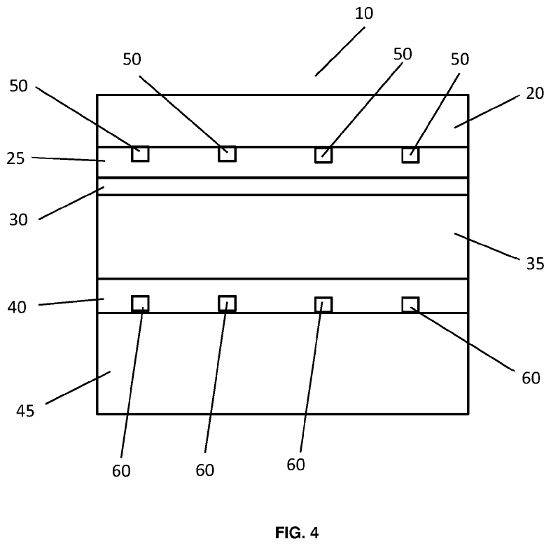

An example of a solar cell device is shown in FIG. 4. Referring to FIG. 4, solar cell device 10 includes transparent conductive layer 20 and transparent conductive layer 45. Each transparent conductive layer can include a transparent conductive oxide (TCO). Hole transport layer (HTL) 25 is adjacent to transparent conductive layer 20 and first perovskite layer 30 opposite transparent conductive layer 20. First perovskite layer 30 can include a 2D-perovskite, which is positioned next to a second perovskite layer 35. Second perovskite layer 35 can include a 3D-perovskite. Electron transport layer (ETL) 40 is adjacent to transparent conductive layer 45 and second perovskite layer 35 opposite transparent conductive layer 45. Hole transport layer 25 can include electrically conductive lines 50. Electron transport layer 40 can include electrically conductive lines 60.

### EXAMPLES

### Device Preparation

A first substrate consisting of fluorine doped tin oxide (FTO) on glass was ultrasonic cleaned with a 1:50 Hellmanex III: deionized water solution for 10 minutes, followed by 10 minutes in deionized water at 50° C., 10 minutes in fresh deionized water at 50° C., 10 minutes in acetone at 50° C., and 10 minutes in 2-propanol at 50° C. The cleaned substrate was dried using an air-drying gun.

The cleaned first substrate was immerged in a solution containing 625 mg urea, 138 mg SnCl₂·2H₂O, 50 mL deionized water, 12.5 μL thioglycolic acid, and 625 μL hydrochloric acid (37 wt %) for 14 hours at 65° C. The first substrate (glass/FTO/SnO₂) was ultrasonic cleaned for 10 minutes in deionized water at 50° C., 10 minutes in fresh deionized water at 50° C., 10 minutes in acetone at 50° C., and 10 minutes in 2-propanol at 50° C. The cleaned substrate was dried using an air-drying gun.

Subsequently, 60 nm thick aluminum metal reinforcement was deposited on top of the first substrate (glass/FTO/SnO₂) by thermal evaporation with an evaporation speed of about 5 nm/s.

The first substrate (glass/FTO/SnO₂ & Al reinforcement) was annealed at ambient air for 1 hour at 170° C., followed by oxygen plasma cleaning for 10 minutes at reduced pressure. A potassium chloride solution was deposited by spin coating (10 mM KCl in deionized water; spin coater setting: 3000 rpm (max) for 20 seconds), followed by an annealing step at 100° C. for 10 minutes.

The first substrate (glass/FTO/SnO₂&Al reinforcement) was transferred into a dry air deposition chamber with a relative humidity below 1%. A perovskite solution consisting of 704 mg lead iodide (PbI₂), 240 mg formamidinium iodide (FAI), 9 mg methylammonium lead bromide (MAPbBr₃), 25 mg methylammonium chloride (MACI), 890 μL N,N-dimethylformamide, and 110 μL dimethyl sulfoxide was deposited at 5000 rpm₍ₘₐₓ₎ for 30 seconds by spin coating. During this spin coating process, 600 μL diethyl ether were deposited dynamically to initiate the perovskite crystallization process. The perovskite film was annealed at 100° C. for 1 hour followed by 150° C. for 5 minutes. Subsequently, a 2D perovskite passivation layer was fabricated by spin coating (4000 rpm₍ₘₐₓ₎ for 30 s) a 15 mM n-hexylammonium bromide solution in chloroform, followed by annealing at 100° C. for 10 minutes.

A second substrate consisting of polyethylene terephthalate coated with indium tin oxide (PET/ITO) was ultrasonic cleaned with a 1:50 Hellmanex III: deionized water solution for 10 minutes, followed by 10 minutes in deionized water at 50° C., 10 minutes in fresh deionized water at 50° C., 10 minutes in acetone at 50° C., and 10 minutes in 2-propanol at 50° C. The cleaned substrates were dried using an air-drying gun.

60 nm thick aluminum metal reinforcement was deposited on top of the ITO by thermal evaporation with an evaporation speed of about 5 nm/s. Subsequently, the second substrate (PET/ITO&Al reinforcement) was oxygen plasma cleaned for 10 minutes at reduced pressure. Subsequently, a hole transport layer of SpiroMeOTAD with [Spiro-MeOTAD][TFSI]₁ in chlorobenzene was deposited by spin coating at 3000 rpm₍ₘₐₓ₎ for 20 seconds in a dry air atmosphere. The second substrate layer sequence is as follows: PET/ITO&Al reinforcement/HTL.

The second substrate was placed upside down on top of the first substrate. The two HTL layers were merged by adhesive bonding: applying pressure on to the substrate stack at room temperature. The full layer sequence is as follows: glass/FTO/SnO₂&Al reinforcement/perovskite/2D perovskite/HTL/ITO&Al reinforcement/PET. The total HTL layer thickness is the combined thicknesses of the two individual HTL layers.

### Electrical Measurement

The FTO and ITO electrodes were electrically contacted through the aluminum reinforced metal structure to ensure a good electrical contact. Under illumination (AM 1.5 G, 100 mW/cm²), a voltage was ramped from 0 V to 1.2 V (forward scan) or from 1.2 V to 0 V (reverse scan) while the current was measured. The measurement was performed when the bifacial solar cell was illuminated through the glass side. A separate pair of measurements with the same measurement conditions was performed but the solar cell was illuminated through the PET side.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. It should also be understood that the appended drawings are not necessarily to scale, presenting a somewhat simplified representation of various features and basic principles of the invention.

1. A solar cell comprising:
a first transparent conductive oxide (TCO) layer proximate to a first charge transport layer;
a second TCO layer proximate to a second charge transport layer;
a perovskite layer disposed between first and second charge transport layers; and
(a) a first plurality of electrically conductive lines disposed between the first TCO layer and the first charge transport layer; or
(b) a second plurality of electrically conductive lines disposed between the second TCO layer and second charge transport layer; or
(c) both (a) and (b).

2. The solar cell of claim 1, wherein the solar cell is a bifacial solar cell.

3. The solar cell of claim 1, wherein the first plurality of electrically conductive lines and second plurality of electrically conductive lines each independently comprise copper (Cu), silver (Ag), zinc (Zn), gold (Au), or aluminum (Al).

4. The solar cell of claim 1, wherein the first charge transport layer comprises Spiro-MeOTAD.

5. The solar cell of claim 1, wherein the second charge transport layer comprises SnO₂.

6. The solar cell of claim 1, wherein the first plurality of electrically conductive lines are configured as a periodic pattern of lines.

7. The solar cell of claim 1, wherein the second plurality of electrically conductive lines are configured as a periodic pattern of lines.

8. The solar cell of claim 1, wherein the first plurality of electrically conductive lines are configured as a grid.

9. The solar cell of claim 1, wherein the second plurality of electrically conductive lines are configured as a grid.

10. The solar cell of claim 1, wherein the first plurality of electrically conductive lines are configured to carry photogenerated current.

11. The solar cell of claim 1, wherein the second plurality of electrically conductive lines are configured to carry photogenerated current.

12. The solar cell of claim 1, further comprising a first adhesive layer disposed between the first TCO layer and the first plurality of electrically conductive lines.

13. The solar cell of claim 12, wherein the first adhesive layer comprises titanium (Ti) or chromium (Cr).

14. The solar cell of claim 12, wherein the first adhesive layer comprises an electrically conductive material.

15. The solar cell of claim 12, wherein the first adhesive layer comprises an electrically insulating material.

16. The solar cell of claim 1, further comprising a second adhesive layer disposed between the second TCO layer and the second plurality of electrically conductive lines.

17. The solar cell of claim 16, wherein the second adhesive layer comprises titanium (Ti), thiophenol, hexanethiol, or trioctylphosphine oxide.

18. The solar cell of claim 16, wherein the second adhesive layer comprises an electrically conductive material.

19. (canceled)

20. A method of producing photogenerated current, comprising:
illuminating a solar cell which comprises:
a first transparent conductive oxide (TCO) layer proximate to a first charge transport layer;
a second TCO layer proximate to a second charge transport layer;
a perovskite layer disposed between first and second charge transport layers; and
(a) a first plurality of electrically conductive lines disposed between the first TCO layer and the first charge transport layer; or
(b) a second plurality of electrically conductive lines disposed between the second TCO layer and second charge transport layer; or
(c) both (a) and (b);
thereby producing photogenerated current.

21. A bifacial solar cell comprising a hole transport layer (HTL), a perovskite layer, an electron transport layer (ETL), wherein the HTL, perovskite, and ETL layers lie between two transparent conductive oxide (TCO) layers, wherein a first metal grid lies within and strengthens the HTL layer, and wherein a second metal grid lies within and strengthens the ETL layer.

22-36. (canceled)
